(19) United States
(12) Patent Application Publication
(10) Pub. No.: US 2025/0259879 A1
(43) Pub. Date: Aug. 14, 2025

(54) MEMBER FOR SEMICONDUCTOR MANUFACTURING EQUIPMENT

(71) Applicant: NGK INSULATORS, LTD., Nagoya-City (JP)

(72) Inventors: Seiya INOUE, Handa-Shi (JP); Tatsuya KUNO, Nagoya-Shi (JP)

(73) Assignee: NGK INSULATORS, LTD., Nagoya-City (JP)

(21) Appl. No.: 18/967,783

(22) Filed: Dec. 4, 2024

Related U.S. Application Data
(63) Continuation of application No. PCT/JP2024/004875, filed on Feb. 13, 2024.

(51) Int. Cl. H01L 21/687

(52) U.S. Cl. CPC H01L 21/68757

(57) ABSTRACT

A member for a semiconductor manufacturing equipment includes a ceramic substrate, wherein the ceramic substrate includes a central portion with a central portion upper surface on which a wafer is to be placed, and an outer peripheral portion with an outer peripheral portion upper surface on which a focus ring is to be placed, the outer peripheral portion being located lower than the central portion upper surface, wherein the central portion includes a central portion plug placement hole that vertically penetrates the central portion, and a central portion plug that is embedded in the central portion plug placement hole, and wherein the outer peripheral portion includes an outer peripheral portion plug placement hole that vertically penetrates the outer peripheral portion, and an outer peripheral portion plug embedded in the outer peripheral portion plug placement hole and having a lower relative permittivity than the central portion plug.

### CROSS REFERENCE TO RELATED APPLICATIONS

The present invention claims the benefit of priority to International Patent Application PCT/JP2024/4875 filed on Feb. 13, 2024 with the Japanese Patent Office, the entire contents of which are incorporated herein by reference in its entirety.

### FIELD OF THE INVENTION

The present invention relates to a member for a semiconductor manufacturing equipment.

### BACKGROUND OF THE INVENTION

Conventionally, members for semiconductor manufacturing equipment used for holding, temperature control, transporting, or the like of wafers have been known. These types of members for semiconductor manufacturing equipment are also called a wafer placement table, an electrostatic chuck, a susceptor, or the like. Generally, they have the function of applying electrical power for electrostatic adsorption to an internal electrode and adsorbing a wafer using electrostatic force. Some members are known that have a function of controlling the temperature of the wafer by flowing gas between the wafer placement surface and the wafer, which is the object to be adsorbed.

An example of a known member for semiconductor manufacturing equipment includes a ceramic substrate having an upper surface on which a wafer is to be placed, a gas flow passage portion that vertically penetrates the ceramic substrate, and a conductive base plate bonded to the lower surface of the ceramic substrate. During wafer processing, a cooling gas such as helium gas is introduced to the back surface of the wafer through the gas flow passage.

In such a member for a semiconductor manufacturing equipment, a large potential difference from the wafer may occur, and discharge (insulation breakdown) may occur between the wafer and the base plate via the gas flow passage portion. For this reason, various techniques for arranging plugs in a gas flow passage portion have been studied in order to suppress discharge. Plugs are often composed of porous materials. If there is no plug, for example, when gas molecules are ionized by the application of an RF voltage, the generated electrons are accelerated and collide with other gas molecules, causing a glow discharge and eventually an arc discharge. However, if there is a plug, it suppresses the discharge because the electrons hit the plug before colliding with other gas molecules.

In addition, during wafer processing, a focus ring is usually placed on the outer periphery side of the wafer for the purpose of uniform processing of the wafer. For this reason, members for a semiconductor manufacturing equipment are sometimes provided with a focus ring placement surface on the outer periphery side of the wafer placement surface. Since the focus ring is used continuously, it is thicker than a wafer from the viewpoint of its lifespan, and since the top surface of the focus ring is to be at the same height as the wafer, a focus ring placement surface is usually set at a position one step lower than the wafer placement surface.

In recent years, there has been an increasing need for wafer processing (for example, deep etching) using high-power plasma. In wafer processing using high-power plasma, a focus ring is also likely to reach high temperatures, so a member for a semiconductor manufacturing equipment has been proposed in which a gas flow passage portion penetrating in the vertical direction is provided even in the outer peripheral portion where a focus ring placement surface is located (see FIG. 8 of Patent Literature 1). With this configuration, a heat transfer gas can be supplied to the focus ring through the gas flow passage portion, thereby cooling the focus ring.

### PRIOR ART

### Patent Literature

[Patent Literature 1] Japanese Patent No. 5357639

### SUMMARY OF THE INVENTION

As described above, in a member for a semiconductor manufacturing equipment, a technique is known in which a gas flow passage portion is provided on the outer peripheral portion where the focus ring placement surface is located, to cool the focus ring. However, if the focus ring placement surface is set at a position one step lower than the wafer placement surface, the thickness of ceramic substrate will be thinner at the outer peripheral portion where the focus ring placement surface is provided than at the central portion where the wafer placement surface is provided. As a result, the vertical length in the outer peripheral portion of the gas flow passage portion, which corresponds to the thickness of the outer peripheral portion of the ceramic substrate, is shorter, and the electric field strength during wafer processing is greater, so the risk of insulation breakdown is higher in the outer peripheral portion than in the central portion.

In view of the above circumstances, an object of one embodiment of the present invention is to provide a member for a semiconductor manufacturing equipment comprising a ceramic substrate having a central portion with a wafer placement surface and an outer peripheral portion with a focus ring placement surface, in which the member for a semiconductor manufacturing equipment has a reduced risk of insulation breakdown in the outer peripheral portion.

The present inventor has made extensive studies to solve the above problems, and has created the present invention as exemplified below.

### Aspect 1

A member for a semiconductor manufacturing equipment, comprising a ceramic substrate,
wherein the ceramic substrate comprises a central portion with a central portion upper surface on which a wafer is to be placed, and an outer peripheral portion with an outer peripheral portion upper surface on which a focus ring is to be placed, the outer peripheral portion being located on an outer peripheral side of the central portion upper surface and lower than the central portion upper surface,
wherein the central portion comprises a central portion plug placement hole that vertically penetrates the central portion, and a central portion plug that is embedded in the central portion plug placement hole, and
wherein the outer peripheral portion comprises an outer peripheral portion plug placement hole that vertically penetrates the outer peripheral portion, and an outer peripheral portion plug embedded in the outer peripheral portion plug placement hole and having a lower relative permittivity than the central portion plug.

### Aspect 2

The member for a semiconductor manufacturing equipment according to aspect 1, wherein the relative permittivity of the outer peripheral portion plug is 0.7 times or less than the relative permittivity of the central portion plug.

### Aspect 3

The member for a semiconductor manufacturing equipment according to aspect 1 or 2, wherein a main component of the central portion plug is the same as a main component of the ceramic substrate.

### Aspect 4

The member for a semiconductor manufacturing equipment according to any one of aspects 1 to 3, wherein the outer peripheral portion plug comprises silica.

### Aspect 5

The member for a semiconductor manufacturing equipment according to any one of aspects 1 to 4, wherein the central portion plug and/or the outer peripheral portion plug is a porous body or a dense body with a flow passage passing an inside the dense body.

### Aspect 6

The member for a semiconductor manufacturing equipment according to any one of aspects 1 to 5, wherein a thickness of the outer peripheral portion is 75% or less of the thickness of the central portion.

According to one embodiment of the present invention, it is possible to provide a member for a semiconductor manufacturing equipment having a reduced risk of insulation breakdown in the outer peripheral portion with a focus ring placement surface. Therefore, the member for a semiconductor manufacturing equipment is suitable for performing wafer processing (for example, deep etching) using high-power plasma, for example.

### BRIEF DESCRIPTION OF THE DRAWINGS

FIG. 1 is a schematic partial longitudinal sectional view of a member for a semiconductor manufacturing equipment according to one embodiment of the present invention.

FIG. 2 is a schematic plan view of a member for a semiconductor manufacturing equipment according to one embodiment of the present invention.

FIGS. 3A-3F show a manufacturing process diagram of a member for a semiconductor manufacturing equipment according to one embodiment of the present invention.

### DETAILED DESCRIPTION OF THE INVENTION

Hereinafter, embodiments of the present invention will now be described in detail with reference to the drawings. It should be understood that the present invention is not intended to be limited to the following embodiments, and any change, improvement or the like of the design may be appropriately added based on ordinary knowledge of those skilled in the art without departing from the spirit of the present invention. In addition, as used herein, “upper” and “lower” are used to conveniently express the relative positional relationship when a member for a semiconductor manufacturing equipment is placed on a horizontal plane with the upper surface of the ceramic substrate facing upward, and they do not represent any absolute positional relationships. Therefore, depending on the orientation of the member for a semiconductor manufacturing equipment, “upper” and “lower” may become “lower” and “upper”, or “left” and “right”, or “front” and “rear”.

### 1. Configuration of Member for Semiconductor Manufacturing Equipment

### 1-1. Overall Configuration

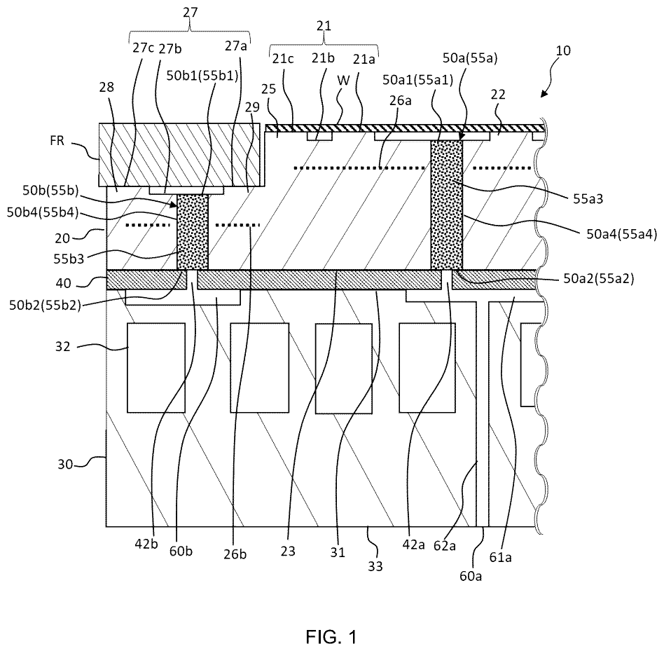

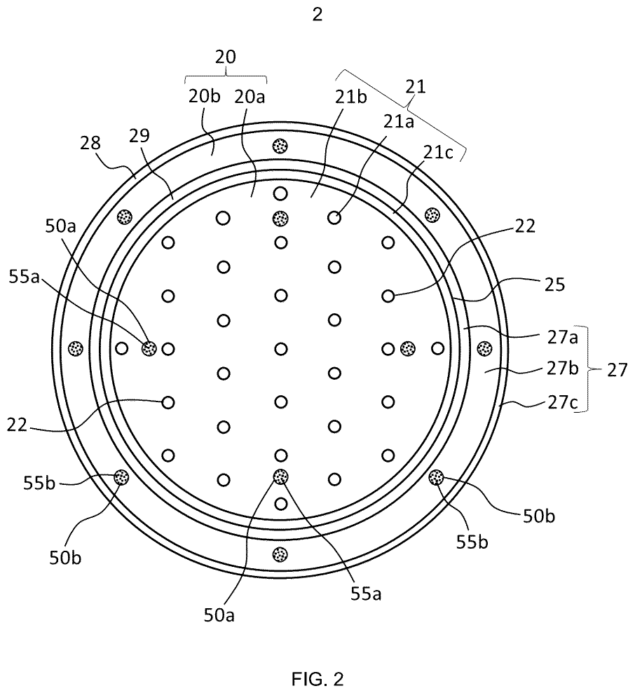

Referring to FIGS. 1 and 2, a member for a semiconductor manufacturing equipment 10 according to an embodiment of the present invention can be used when performing processes such as CVD and etching on a wafer W by utilizing plasma. The member for a semiconductor manufacturing equipment 10 comprises a ceramic substrate 20 which comprises a central portion 20a with a central portion upper surface 21 on which a wafer W is to be placed, and an outer peripheral portion 20b with an outer peripheral portion upper surface 27 on which a focus ring FR is to be placed, the outer peripheral portion 20b being located on the outer peripheral side of the central portion upper surface 21 and lower than the central portion upper surface 21.

The central portion 20a comprises a central portion plug placement hole 50a that vertically penetrates the central portion 20a, and a central portion plug 55a that is embedded in the central portion plug placement hole 50a, and the outer peripheral portion 20b comprises an outer peripheral portion plug placement hole 50b that vertically penetrates the outer peripheral portion 20b, and an outer peripheral portion plug 55b embedded in the outer peripheral portion plug placement hole 50b and having a lower relative permittivity than the central portion plug 55a.

Further, the member for a semiconductor manufacturing equipment 10 also comprises a base plate 30 that is located on the side of the lower surface 23 of the ceramic substrate 20 and has an internal refrigerant passage 32. The ceramic substrate 20 and the base plate 30 can be bonded together via a bonding layer 40.

### 1-2. Ceramic Substrate

The ceramic substrate 20 can be made of a ceramic material such as an alumina sintered body or an aluminum nitride sintered body.

The central portion 20a of the ceramic substrate 20 has, for example, a circular central portion upper surface 21 in a plan view (FIG. 2). The diameter of the central portion 20a can be typically 190 to 450 mm, and more typically 300 to 350 mm.

A wafer W can be placed on the central portion upper surface 21. In one embodiment, a plurality of protrusions 22 for placing the wafer W are provided over the entire surface on the central portion upper surface 21 of the ceramic substrate 20. Although the shape of the protrusion 22 is not limited, it can be, for example, a cylinder, a prism, or the like. In addition, an annular seal band 25 may be formed along the outer edge of the central portion upper surface 21. In this case, the wafer W may be supported by the upper end surface 21c of the seal band 25 and the upper end surfaces 21a of the plurality of protrusions 22. It is preferable that the seal band 25 and the protrusions 22 have the same height, and the height is, for example, 5 to 100 μm, and typically 10 to 30 μm. In addition, the portion of the upper surface 21 of the ceramic substrate 20 where the seal band 21a and the protrusions 22 are not provided is referred to as the reference surface 21b.

The thickness of the central portion 20a of the ceramic substrate 20 is not limited, but from the viewpoint of increasing the fixing strength of the central portion plug 55a, it is preferably 1 mm or more. In addition, from the viewpoint of heat transfer and reducing the manufacturing cost of the ceramic substrate 20, the thickness is preferably 5 mm or less, more preferably 3 mm or less, and even more preferably 2 mm or less. Therefore, the thickness of the central portion 20a is, for example, preferably 1 to 5 mm, more preferably 1 to 3 mm, and even more preferably 1 to 2 mm.

The outer peripheral portion 20b of the ceramic substrate 20 has, for example, an outer peripheral portion upper surface 27 having an annular shape in a plan view on the outer periphery of the central portion 20a. The focus ring FR can be placed on the outer peripheral portion upper surface 27, which is one step lower than the central portion upper surface 21.

In one embodiment, on the outer peripheral portion upper surface 27 of ceramic substrate 20, for the purpose of placing the focus ring FR, annular seal bands 28 and 29 are formed along the inner and outer edges of outer peripheral portion upper surface 27 of ceramic substrate 20, respectively. In this case, the focus ring FR may be supported by the upper end surfaces 27c, 27a of the seal bands 28, 29. The height of the seal bands 28, 29 may be, for example, 5 to 100 μm, and typically 10 to 30 μm. In addition, the portion of the outer peripheral portion upper surface 27 of the ceramic substrate 20 on which the seal bands 28, 29 are not provided is referred to as a reference surface 27b.

In one embodiment, the thickness of the outer peripheral portion 20b is 75% or less, preferably 60% or less, of the thickness of the central portion 20a. Although there is no particular lower limit for the thickness of the outer peripheral portion 20b relative to the thickness of the central portion 20a, the thickness of the outer peripheral portion 20b is typically 40 to 75% of the thickness of the central portion 20a. More typically, the thickness of the outer peripheral portion 20b is 50 to 60% of the thickness of the central portion 20a.

The lower surfaces 23 of the central portion 20a and the outer peripheral portion 20b may be flush with each other.

The central portion plug placement hole 50a and the outer peripheral portion plug placement hole 50b are a hole that vertically penetrates the ceramic substrate 20. The central portion plug placement hole 50a (the outer peripheral portion plug placement hole 50b) is a gas flow passage from the lower surface 23 of the ceramic substrate 20 to the reference surface 21b of the central portion upper surface 21 (reference surface 27b of the outer peripheral portion upper surface 27). The opening diameter (if the cross section of the plug placement hole is not circular, it means the equivalent circle diameter.) of the central portion plug placement hole 50a (the outer peripheral portion plug placement hole 50b) in the horizontal direction is not limited, but may be within the range of 1 to 5 mm, typically within the range of 3 to 4 mm, at any height position.

The central portion plug placement hole 50a (the outer peripheral portion plug placement hole 50b) may have the same opening diameter from top to bottom. In addition, the central portion plug placement hole 50a (outer peripheral portion plug placement hole 50b) may have a tapered inner peripheral surface 50a4 (inner peripheral surface 50b4) whose area of the upper opening 50a1 (the upper opening 50b1) is larger than the area of the lower opening 50a2 (the lower opening 50b2). Therefore, the central portion plug placement hole 50a (the outer peripheral portion plug placement hole 50b) can have, for example, a cylindrical, prismatic, truncated conical or truncated pyramid space, and among these, it is preferable for it to have a truncated conical or truncated pyramid space.

Because the central portion plug placement hole 50a (the outer peripheral portion plug placement hole 50b) has a tapered inner peripheral surface 50a4 (the inner peripheral surface 50b4), when embedding the central portion plug 55a (the outer peripheral portion plug 55b) in the central portion plug placement hole 50a (the outer peripheral portion plug placement hole 50b), the central portion plug 55a (the outer peripheral portion plug 55b) becomes likely to stop at a predetermined height position in the central portion plug placement hole 50a (the outer peripheral portion plug placement hole 50b), and as a result, an effect can be achieved that the central portion plug 55a (the outer peripheral portion plug 55b) can be embedded in the central portion plug placement hole 50a (the outer peripheral portion plug placement hole 50b) with high positioning accuracy. Further, while the central portion plug 55a (the outer peripheral portion plug 55b) becomes difficult to come out downward, it becomes relatively easy to come out upward, so that the effect of making it easy to replace the central portion plug 55a (the outer peripheral portion plug 55b) can be obtained. Furthermore, since the creepage distance becomes longer, an effect of suppressing discharge can also be obtained.

A plurality of central portion plug placement holes 50a (four in FIG. 2) are provided, and a plurality of outer peripheral portion plug placement holes 50b (eight in FIG. 2) are also provided. The locations of the central portion plug placement holes 50a and the outer peripheral portion plug placement holes 50b may be appropriately set in consideration of uniform gas supply to the entire back surface of the wafer W and the entire back surface of the focus ring FR. For example, it is preferable that the central portion plug placement holes 50a and the outer peripheral portion plug placement holes 50b are provided at equal intervals in the peripheral direction. There is no particular limitation on the method for fixing the central portion plug 55a (the outer peripheral portion plug 55b) to the central portion plug placement hole 50a (the outer peripheral portion plug placement hole 50b), and for example, the outer peripheral surface 55a4 (the outer peripheral surface 55b4) of the central portion plug 55a (the outer peripheral portion plug 55b) and the inner peripheral surface 50a4 (the inner peripheral surface 50b4) of the central portion plug placement hole 50a (the outer peripheral portion plug placement hole 50b) may be fixed so as to directly fit together. An example of a direct fitting method is to press-fit the central portion plug 55a (the outer peripheral portion plug 55b) into the central portion plug placement hole 50a (the outer peripheral portion plug placement hole 50b) to embed the plug.

It is preferable that the central portion plug 55a (the outer peripheral portion plug 55b) has an outer shape that is the same as that of the central portion plug placement hole 50a (the outer peripheral portion plug placement hole 50b) (for example, cylindrical, prismatic, truncated cone, or truncated pyramid). In this case, in order to obtain the desired fixation strength, it is preferable that the cross-sectional diameter in the horizontal direction at any height position of the central portion plug 55a (the outer peripheral portion plug 55b) is made slightly larger (for example, by about 5 to 20 μm in equivalent circle diameter) than the horizontal cross-sectional diameter of the central portion plug placement hole 50a (the outer peripheral portion plug placement hole 50b) located at the same height position. Further, as a direct fitting method, there is also a method in which a male threaded portion provided on the outer peripheral surface 55a4 (the outer peripheral surface 55b4) of the central portion plug 55a (the outer peripheral portion plug 55b) is screwed into a female threaded portion provided on the inner peripheral surface 50a4 (the inner peripheral surface 50b4) of the central portion plug placement hole 50a (the outer peripheral portion plug placement hole 50b). Furthermore, the outer peripheral surface 55a4 (the outer peripheral surface 55b4) of the central portion plug 55a (the outer peripheral portion plug 55b) may be bonded to the inner peripheral surface 50a4 (the inner peripheral surface 50b4) of the central portion plug placement hole 50a (the outer peripheral portion plug placement hole 50b) via an adhesive. However, when using an adhesive for fixing, the adhesive is likely to wear out or deteriorate, resulting in a decrease in the fixing strength of the central potion plug 55a (the outer peripheral potion plug 55b). Therefore, it is preferable to adopt a direct fitting method. If the two are directly fitted, no gap will be created between the central potion plug 55a (the outer peripheral portion plug 55b) and the central portion plug placement hole 50a (the outer peripheral portion plug placement hole 50b) caused by deterioration due to corrosion or erosion of the adhesive. Therefore, there is an advantage that discharge and falling off of the plugs due to deterioration of the adhesive can be prevented.

The height position of the upper surface 55a1 (the upper surface 55b1) of the central portion plug 55a (the outer peripheral portion plug 55b) is not limited. Therefore, it may be set to the same height as the reference surface 21b (the reference surface 27b) of the ceramic substrate 20, or may be set to a different height. However, it is preferable that the height position of the upper surface 55a1 (the upper surface 55b1) of the central portion plug 55a (the outer peripheral portion plug 55b) be the same height as the reference surface 21b (the reference surface 27b). When the upper surface 55a1 (upper surface 55b1) of the central portion plug 55a (the outer peripheral portion plug 55b) is made lower than the reference surface 21b (the reference surface 27b), it is preferable to place it at a lower position within a range of 0.5 mm or less (preferably 0.2 mm or less, and more preferably 0.1 mm or less) in order to suppress the occurrence of discharge. When the upper surface 55a1 (the upper surface 55b1) of the central portion plug 55a (the outer peripheral portion plug 55b) is made higher than the reference surface 21b (the reference surface 27b), there is no particular restriction as long as it is made lower than the upper end surface 21a (the upper end surfaces 27c, 27a) of the protrusion 22 (the seal band 28 and seal band 29) and the outflow of the gas from the central portion plug 55a (the outer peripheral portion plug 55b) is not hindered.

There is no particular restriction on the height position of the lower surface 55a2 (the lower surface 55b2) of the central portion plug 55a (the outer peripheral portion plug 55b), and the lower surface 55a2 (the lower surface 55b2) may be the same height as the lower surface 23 of the ceramic substrate 20, or may be a different height. For example, the lower surface 55a2 (the lower surface 55b2) of the central portion plug 55a (the outer peripheral portion plug 55b) may protrude below the lower surface 23 of the ceramic substrate 20, or the lower surface 55a2 (the lower surface 55b2) of the central portion plug 55a (the outer peripheral portion plug 55b) may be located above the lower surface 23 of the ceramic substrate 20. However, in either case, it is preferable that at least a part of the lower surface 55a2 (the lower surface 55b2) contacts a bonding layer 40 from the viewpoint of suppressing discharge.

As can be seen from FIG. 1, the outer peripheral portion upper surface 27 constituting the focus ring placement surface is set at a position one step lower than the central portion upper surface 21 constituting the wafer placement surface, and the thickness of ceramic substrate 20 is thinner at the outer peripheral portion 20b than at the central portion 20a. Therefore, during wafer processing, a greater electric field strength is applied to the outer peripheral portion plug 55b embedded in the outer peripheral portion plug placement hole 50b than to the central portion plug 55a embedded in the central portion plug placement hole 50a. However, since the outer peripheral portion plug 55b has a lower relative permittivity than the central portion plug 55a, the voltage drop in the outer peripheral portion plug 55b is promoted, thereby suppressing a sudden voltage drop near the lower surface of the outer peripheral portion plug 55b and making it less likely for insulation breakdown to occur. Although it is not intended that the present invention be limited by any theory, such a mechanism can reduce the risk of insulation breakdown at the outer peripheral portion of the focus ring.

The above mechanism will be specifically described below. The central portion plug 55a and the outer peripheral portion plug 55b can each be regarded as a pseudo-capacitor. In this case, the capacitance C1 of the central portion plug 55a can be roughly calculated by the following formula A. The capacitance C2 of the outer peripheral portion plug 55b can be roughly calculated by the following formula B.

$${C}_{1} = ( {ε}_{0} \times {ε}_{r 1} \times {S}_{1} ) / {d}_{1} \qquad Formula A$$

(in which, ε₀ represents the relative permittivity of vacuum, εᵣ₁ represents the relative permittivity of the central portion plug 55a, S₁ represents the area of the upper surface 55a1 of the central portion plug 55a, and d₁ represents the thickness of the central portion 20a≈the thickness of the central portion plug 55a.)

$${C}_{2} = ( {ε}_{0} \times {ε}_{r 2} \times {S}_{2} ) / {d}_{2} \qquad Formula B$$

(in which, ε₀ represents the relative permittivity of vacuum, εᵣ₂ represents the relative permittivity of the outer peripheral portion plug 55b, S₂ represents the area of the upper surface 55b1 of the outer peripheral portion plug 55b, and d₂ represents the thickness of the outer peripheral portion 20b≈the thickness of the outer peripheral portion plug 55b.)

Accordingly, for example, when the thickness of the outer

peripheral portion 20b is half the thickness of the central portion 20a (that is, d₂=0.5×d₁), and the area of the upper surface 55a1 of the central portion plug 55a is the same as the area of the upper surface 55b1 of the outer peripheral portion plug 55b (S₁=S₂), if the relative permittivity of the outer peripheral portion plug 55b and the central portion plugs 55 are set to be the same (εᵣ₁=εᵣ₂), the capacitance of the outer peripheral portion plug 55b becomes twice that of the central portion plug 55a, and the voltage drop in the outer peripheral portion plug 55b becomes smaller. As a result, a sudden voltage drop is likely to occur near the lower surface 55b2 of the outer peripheral portion plug 55b, increasing the risk of insulation breakdown.

In contrast, when the thickness of the outer peripheral portion 20b is half the thickness of the central portion 20a (that is, d₂=0.5×d₁), and the area of the upper surface 55a1 of the central portion plug 55a is the same as the area of the upper surface 55b1 of the outer peripheral portion plug 55b (S₁=S₂), if the relative permittivity of the outer peripheral portion plug 55b is set to half that of the central portion plug 55a (εᵣ₂=0.5×εᵣ₁), the electrostatic capacitance of the central portion plug 55a and the outer peripheral portion plug 55b can be made approximately the same. As a result, the voltage drops in the outer peripheral portion plug 55b and the central portion plug 55a become approximately the same, so that a sudden voltage drop near the lower surface of the outer peripheral portion plug 55b is suppressed. In this way, the risk of insulation breakdown near the lower surface 55b2 of the outer peripheral portion plug 55b can be reduced compared to the case where εᵣ₁=εᵣ₂.

From the viewpoint of enhancing the effect of reducing the risk of insulation breakdown in the outer peripheral portion 20b of the ceramic substrate 20, the relative permittivity of the outer peripheral portion plug 55b is preferably 0.7 times or less, and more preferably 0.5 times or less of the relative permittivity of the central portion plug 55a. Although no particular lower limit is set for the relative permittivity of the outer peripheral portion plug 55b, it is also affected by the ratio of the thickness of the central portion 20a to that of the outer peripheral portion plug 55b. Considering the typical ratio of the thickness of the outer peripheral portion plug 55b to that of the central portion 20a and the ease of control of the relative permittivity, the relative permittivity of the outer peripheral portion plug 55b is preferably 0.2 to 0.7 times, more preferably 0.2 to 0.5 times as high as the relative permittivity of the central portion plug 55a.

In one embodiment, the central portion plug 55a has a relative permittivity of 7 or more, and the outer peripheral portion plug 55b has a relative permittivity of 5 or less. In a preferred embodiment, the central portion plug 55a has a relative permittivity of 7 or more, and the outer peripheral portion plug 55b has a relative permittivity of 4 or less. In a more preferred embodiment, the central portion plug 55a has a relative permittivity of 10 or more, and the outer peripheral portion plug 55b has a relative permittivity of 4 or less. Illustratively, the central portion plug 55a has a relative permittivity of 7 to 12, and the outer peripheral portion plug 55b has a relative permittivity of 2 to 5. Typically, the central portion plug 55a has a relative permittivity of 7 to 10,and the outer peripheral portion plug 55b has a relative permittivity of 3 to 4.

As used herein, the relative permittivity of the plugs, such as the central portion plug 55a and the outer peripheral portion plug 55b, is measured by removing the plug from the ceramic substrate and sandwiching the upper surface and the lower surface of the plug between a pair of electrodes and using an impedance analyzer (for example, an impedance analyzer 4291A manufactured by Keysight Technologies) at a room temperature and in a normal humidity environment. As described later, the plug may be constructed by stacking a plurality of plugs made of different materials. In this case, the relative permittivity of the plug is the value of the entire plug measured according to the above-described method.

The material constituting the central portion plug 55a and the outer peripheral portion plug 55b may be ceramic, and may contain, for example, one or more selected from aluminum oxide, aluminum nitride, silicon carbide, silica, yttria, and zirconia. They may also be composed of only one or two selected from aluminum oxide, aluminum nitride, silica, yttria, and zirconia excluding impurities.

Among these, the central portion plug 55a is preferably made of a material with high corrosion resistance since it is often exposed to corrosive gases. Therefore, it is preferable that the central portion plug 55a contain one or more selected from aluminum oxide, aluminum nitride, yttria, and zirconia, and it is more preferable that the central portion plug 55a is composed of one or two selected from aluminum oxide and aluminum nitride excluding impurities, and it is even more preferable that the central portion plug 55a is composed of aluminum oxide excluding impurities.

Furthermore, the main component of the central portion plug 55a is preferably the same as the main component of the ceramic substrate 20 in order to make the coefficient of thermal expansion closer to each other and maintain the fixing strength of the plug. Here, the term “main component” refers to a component that occupies 50% by mass or more of the target object. For example, if the main component of the ceramic substrate 20 is aluminum oxide, it is preferable that the main component of the central portion plug 55a is also aluminum oxide.

On the other hand, since the outer peripheral portion plug 55b is isolated from the corrosive gas by the focus ring, there is little need to consider corrosion resistance. For this reason, it is preferable to select a material that has a low relative permittivity, and therefore it is preferable that the outer peripheral portion plug 55b contains silica. Further, from the viewpoint of balancing the demand for lowering the relative elative permittivity and the demand for making the coefficient of thermal expansion closer to that of the ceramic substrate, it is more preferable for the material to contain silica and aluminum oxide. Furthermore, the outer peripheral portion plug 55b may be made of silica excluding impurities, or may be made of silica and aluminum oxide excluding impurities. An example of silica is quartz. Therefore, it is preferable that the outer peripheral portion plug 55b be made of quartz and aluminum oxide excluding impurities, or be made of quartz excluding impurities.

Each of the central portion plug 55a and the outer peripheral portion plug 55b can also be constructed by stacking a plurality of plugs made of different materials in the vertical direction. In this case, the upper plug can be made of a ceramic with a higher volume resistivity than the lower plug, and the lower plug can be brought into contact with a base plate or an electrical conductor, thereby lowering the potential of the lower plug and suppressing discharge in the lower side, where there is a large space and discharge is more likely to occur. Specifically, the central portion plug 55a may have an upper plug made of aluminum oxide and a lower plug made of silicon carbide, which may be arranged sequentially in the plug placement hole, while the outer peripheral portion plug 55b may have an upper plug made of aluminum oxide and a lower plug made of quartz, which may be arranged sequentially in the plug placement hole.

The central portion plug 55a and the outer peripheral portion plug 55b have gas flow passages 55a3 and 55b3 that penetrate the inside thereof, respectively. In one embodiment, the central portion plug 55a has a structure in which gas flowing in from a lower surface 55a2 of the central portion plug 55a flows through the gas flow passage 55a3 and flows out from the upper surface 55a1 of the central portion plug 55a. In addition, in one embodiment, the outer peripheral portion plug 55b has a structure in which gas flowing in from the lower surface 55b2 of the outer peripheral portion plug 55b flows through the gas flow passage 55b3 and flows out from the upper surface 55b1 of the outer peripheral portion plug 55b.

In one embodiment, in the central portion plug 55a, one or more gas flow passages 55a3 may be formed by vertically penetrating a dense body that does not allow gas flow. In addition, in the outer peripheral portion plug 55b, one or more gas flow passage 55b3 may be formed by vertically penetrating a dense body that does not allow gas flow. The gas flow passage 55a3 (the gas flow passage 55b3) may be configured with any of straight lines, curved lines, or a combination of both, but rom the viewpoint of suppressing discharge, it is preferable to have a shape such that the length of the flow path is longer than the thickness (length in the vertical direction) of the central portion plug 55a (the outer peripheral portion plug 55b), for example, a curved shape such as a spiral or zigzag shape. The fact that the central portion plug 55a (the outer peripheral portion plug 55b) is a dense body means that the porosity of the central portion plug 55a (the outer peripheral portion plug 55b) is 5% or less. In this case, the porosity of the central portion plug 55a (the outer peripheral portion plug 55b) is preferably 1% or less, and more preferably 0.5% or less.

Therefore, in one embodiment of the present invention, the central portion plug 55a is made of dense alumina and has one or more gas flow passages 55a3 formed inside it, and the outer peripheral portion plug 55b is a dense body made of quartz and has one or more gas flow passages 55b3 formed inside it.

The porosity of the plugs such as the central portion plug 55a and the outer peripheral portion plug 55b is measured by the following method. The plug is cut such that a cross section passing through the central axis extending in the vertical direction of the plug is exposed. Next, the portion of the cross section excluding the gas passage is observed using a scanning electron microscope (SEM) at a magnification of 3000 times in approximately 2200 μm², and the area ratio of pores confirmed in the portion is calculated. Specifically, by analyzing the SEM image, a threshold value is determined from the luminance distribution of luminance data of pixels in the image using a discriminant analysis method (Otsu's binarization). Thereafter, each pixel in the image is binarized into solid portions and pore portions based on the determined threshold value, and the area of the solid portions and the area of the pore portions are calculated. Then, the ratio of the area of the pores to the total area (the total area of the solid portions and the pore portions) is determined. The same measurements are performed at five locations on the same plug, and the average value of the measurements at five locations is taken as the porosity of the plug.

As a method of manufacturing the plug having a gas flow passage in a dense body, mention may be made to a method of firing a formed body formed using additive manufacturing technology such as a 3D printer, and a method of firing a formed body formed by mold casting using a master mold produced by a lost-wax method, for example. Mold casting is disclosed in, for example, Japanese Patent No. 7144603.

Alternatively, the central portion plug 55a (the outer peripheral portion plug 55b) may be constituted by a porous material, which may be used as the gas flow passage 55a3 (the gas flow passage 55b3). In this case, gas flowing in from the lower surface 55a2 (the lower surface 55b2) of the central portion plug 55a (the outer peripheral portion plug 55b) flows through the gas flow passage 55a3 (the gas flow passage 55b3) formed by a large number of continuous pores, and flows out from the upper surface 55a1 (the upper surface 55b1) of the central portion plug 55a (the peripheral portion plug 55b). Since three-dimensional (for example, three-dimensional network) continuous pores that exist within the porous material serve as gas passages, the substantial passage length within the gas flow passage 55a3 (the gas flow passage 55b3) becomes longer compared to the case where the gas flow passage 55a3 (the gas flow passage 55b3) is hollow, and an effect that electric discharge is less likely to occur can be obtained. In one embodiment, the central portion plug 55a (the outer peripheral portion plug 55b) may be entirely porous. In another embodiment, in the central portion plug 55a (the outer peripheral portion plug 55b), a porous gas flow passage can be formed on the inner peripheral side of the dense outer peripheral surface 55a4 (the outer peripheral surface 55b4). It is also possible to further form one or more gas flow passages in the porous gas flow passage.

Therefore, the gas flow passage 55a3 (the gas flow passage 55b3) may be hollow or porous. It is preferable that at least a portion of the gas flow passage 55a3 (the gas flow passage 55b3) be porous. The fact that the gas flow passage 55a3 (the gas flow passage 55b3) is hollow means that the porosity is 100%. The fact that the gas flow passage 55a3 (the gas flow passage 55b3) is porous means that the porosity of the gas flow passage 55a3 (the gas flow passage 55b3) is greater than 5% and less than 100%. The porosity of the gas flow passage 55a3 (the gas flow passage 55b3) is preferably large in order to reduce ventilation resistance. Therefore, the porosity of the gas flow passage 55a3 (the gas flow passage 55b3) is preferably 10% or more, more preferably 40% or more. On the other hand, the porosity of the gas flow passage 55a3 (the gas flow passage 55b3) is preferably 50% or less in order to lengthen the passage length of the plug 55 and ensure structural strength. Therefore, the porosity of the gas flow passage 55a3 (the gas flow passage 55b3) is preferably 10% or more and 50% or less, and more preferably 40% or more and 50% or less.

The porosity of the gas flow passage 55a3 (the gas flow passage 55b3) is measured by mercury porosimetry method (JIS R1655: 2003).

The porosity of the central portion plug 55a (the outer peripheral portion plug 55b) can be controlled, for example, by adjusting the content of the pore-forming material in the raw material composition before producing by firing the ceramics which they are made of. For example, in order to make the outer peripheral surface 55a4 (the outer peripheral surface 55b4) of the central portion plug 55a (the outer peripheral portion plug 55b) denser, the amount of pore-forming material near the outer peripheral surface may be partially reduced or may not be used.

As used herein, when the gas flow passage 55a3 (the gas flow passage 55b3) of the central portion plug 55a (the outer peripheral portion plug 55b) is porous, the central portion plug 55a (the outer peripheral portion plug 55b) is treated as being porous. Therefore, when the flow path penetrating the interior of the dense central portion plug 55a (the outer peripheral portion plug 55b) is porous, the central portion plug 55a (the outer peripheral portion plug 55b) can be recognized as a porous body, or can also be recognized as a dense body having a flow passage penetrating the inside thereof.

An electrode 26a is incorporated in the central portion 20a of the ceramic substrate 20. The electrode 26a is a planar electrode used as an electrostatic electrode, and is connected to an external DC power source via a power supply member (not shown). The electrode 26a is formed of a material containing, for example, W, Mo, WC, MoC, or the like. A low-pass filter may be placed in the middle of the power supply member. The power supply member is electrically insulated from the bonding layer 40 and the base plate 30. When a DC voltage is applied to this electrode 26a, the wafer W is adsorbed and fixed to the wafer placement surface (specifically, the upper end surface 21c of the seal band 25 and the upper end surface 21a of the protrusion 22) by electrostatic attraction force, and when the application of the DC voltage is released, the adsorption and fixation of the wafer W to the wafer placement surface is released. As the electrode 26a, a heater electrode (resistance heating element) may be incorporated instead of or in addition to the electrostatic electrode. In that case, a heater power source is connected to the heater electrode. One layer of electrode may be provided inside the central portion 20a of the ceramic substrate 20, or two or more layers which are spaced apart from each other may be provided inside the central portion 20a of the ceramic substrate 20.

An electrode 26b can also be incorporated in the outer peripheral portion 20b of the ceramic substrate 20. The electrode 26b is a planar electrode used as an electrostatic electrode, and is connected to an external DC power source via a power supply member (not shown). The electrode 26b is formed of a material containing, for example, W, Mo, WC, MoC, or the like. A low-pass filter may be placed in the middle of the power supply member. The power supply member is electrically insulated from the bonding layer 40 and the base plate 30. When a DC voltage is applied to this electrode 26b, the wafer W is adsorbed and fixed to the wafer placement surface (specifically, the upper end surface 27c of the seal band 28 and the upper end surface 27a of the seal band 29) by electrostatic attraction force, and when the application of the DC voltage is released, the adsorption and fixation of the wafer W to the wafer placement surface is released. As the electrode 26b, a heater electrode (resistance heating element) such as a ring heater may be incorporated instead of or in addition to the electrostatic electrode. In that case, a heater power source is connected to the heater electrode. One layer of electrode may be provided inside the outer peripheral portion 20b of the ceramic substrate 20, or two or more layers which are spaced apart from each other may be provided inside the outer peripheral portion 20b of the ceramic substrate 20.

### 1-3. Base Plate

In one embodiment, the base plate 30 is a circular plate (having a diameter equal to or larger than that of the outer peripheral portion 20b of the ceramic substrate 20) with good electrical conductivity and thermal conductivity. Examples of the material of the base plate 30 include metal materials and composite materials of metal and ceramics. Examples of the metal material include Al, Ti, Mo, W, and alloys thereof. Examples of composite materials of metal and ceramics include metal matrix composites (MMC) and ceramic matrix composites (CMC). Specific examples of such composite materials include materials containing Si, SiC, and Ti (also referred to as SiSiCTi), materials in which porous SiC is impregnated with Al and/or Si, and composite materials of Al₂O₃ and TiC. A material in which a porous SiC body is impregnated with Al is called AlSiC, and a material in which a porous SiC body is impregnated with Si is called SiSiC. It is preferable to select a material for the base plate 30 that has a coefficient of thermal expansion close to that of the material for the ceramic substrate 20. For example, when the ceramic substrate 20 is made of alumina, the base plate is preferably made of SiSiCTi or AlSiC.

Inside the base plate 30, a refrigerant passage 32 through which refrigerant circulates may be formed. The refrigerant flowing through the refrigerant passage 32 is preferably liquid and preferably electrically insulating. Examples of the electrically insulating liquid include fluorine-based inert liquids. The refrigerant passage 32 can be formed, for example, in a single stroke across the entire base plate 30 from one end (inlet) to the other end (outlet) in a plan view. A supply port and a recovery port of an external refrigerant device (not shown) are connected to the one end and the other end of the refrigerant passage 32, respectively. The refrigerant supplied from the supply port of the external refrigerant device to the one end of the refrigerant passage 32 passes through the refrigerant passage 32 and then returns from the other end of the refrigerant passage 32 to a recovery port of the external refrigerant device, and after the temperature has been adjusted, the refrigerant is again supplied to the one end of the refrigerant passage 32 from the supply port. The base plate 30 is connected to a radio frequency (RF) power source and can also be used as an RF electrode.

The base plate 30 may have a gas supply path 60a for supplying gas to the gas flow passage 55a3 of the central portion plug 55a. In addition, the base plate 30 may also have a gas supply path 60b for supplying gas to the gas flow passage 55b3 of the outer peripheral portion plug 55b. There are no particular limitations on the configuration of the gas supply paths 60a and 60b. For example, as shown in FIG. 1, the gas supply path 60a may have a recess 61a provided in the upper surface 31 of the base plate 30, and a gas introduction portion 62a that supplies the gas introduced from the lower surface 33 of the base plate 30 to the recess 61a. In this case, when the recess 61a is covered with the bonding layer 40, the bonding layer 40 serves as the upper wall of the gas supply path 60a. The gas supply path 60b may have the same structure. The gas supply path 60a and the gas supply path 60b may be in communication with each other. Alternatively, the gas supply path 60a and the gas supply path 60b may be configured such that the gas flows independently.

As shown in FIG. 1, the upper surface 31 of the base plate 30 is bonded to the lower surface 23 of the ceramic substrate 20 via a bonding layer 40. The bonding layer 40 is formed by, for example, TCB (thermal compression bonding). TCB is a known method in which a metal bonding material is sandwiched between two members to be bonded, and the two members are pressure bonded while being heated to a temperature no higher than the solidus temperature of the metal bonding material. The bonding layer 40 can be composed of a metal bonding layer using, for example, an Al-Mg-based bonding material or an Al—Si—Mg-based bonding material. The bonding layer 40 may be a layer formed of solder or a metal brazing material. Furthermore, the bonding layer 40 may be composed of a resin adhesive layer instead of the metal bonding layer. Examples of the material for the resin adhesive layer include silicone resin-based adhesives, epoxy resin-based adhesives, and acrylic resin-based adhesives. In order to improve the uniformity of the thickness of the resin adhesive layer, a spacer (not shown) may be placed between the upper surface 31 of the base plate 30 and the lower surface 23 of the ceramic substrate 20.

The bonding layer 40 has a through hole 42a which communicates with the gas flow passage 55a3 of the central portion plug 55a and also communicates with a gas supply path 60a for supplying gas to the gas flow passage 55a3 of the central portion plug 55a. In addition, the bonding layer 40 also has a through hole 42b which communicates with the gas flow passage 55b3 of the outer peripheral portion plug 55b and also communicates with a gas supply path 60b for supplying gas to the gas flow passage 55b3 of the outer peripheral portion plug 55b.

A plurality of through holes 42a (through holes 42b) may be provided for one central portion plug 55a (the outer peripheral portion plug 55b), and in this case, it is preferable that the plurality of through holes 42a (through holes 42b) be provided point-symmetrically with respect to the central axis of the central portion plug 55a (the outer peripheral portion plug 55b) extending in the vertical direction. Providing a plurality of through holes 42a (through holes 42b) can reduce the size of each through hole 42a (through hole 42b) rather than using one large through hole 42a (through hole 42b), thereby reducing the risk of electrical discharge. Further, by providing a plurality of through holes 42a (through holes 42b), a necessary gas flow rate can be ensured.

Further, a lift pin hole may be provided that penetrates the member for a semiconductor manufacturing equipment 10. The lift pin hole is a hole through which a lift pin for moving the wafer W up and down with respect to the central portion upper surface 21 of the ceramic substrate 20 is inserted. Lift pin holes are provided, for example, at three locations when the wafer W is supported by three lift pins.

### 2. How to use a Member for Semiconductor Manufacturing Equipment

Next, a method of using the member for a semiconductor manufacturing equipment 10 thus configured will be exemplified. First, with the member for a semiconductor manufacturing equipment 10 installed in a chamber (not shown), a focus ring FR is placed on outer peripheral portion upper surface 27 of ceramic substrate 20, and wafer W is placed on central portion upper surface 21 of ceramic substrate 20. Then, the pressure inside the chamber is reduced with a vacuum pump and adjusted to the desired degree of vacuum, and a voltage is applied to the electrode 26a and electrode 26b of the ceramic substrate 20 to generate electrostatic adsorption force, and the wafer W is adsorbed and fixed to the wafer placement surface (specifically, the upper end surface 21c of the seal band 25 and the upper end surface 21a of the protrusion 22), and the focus ring FR is adsorbed and fixed to the focus ring placement surface (specifically, the upper end surface 27c of the seal band 28 and the upper end surface 27a of the seal band 29).

Next, the inside of the chamber is set to a reaction gas atmosphere at a predetermined pressure (for example, several tens to several hundreds of Pa), and in this state, a high frequency voltage such as an RF voltage is applied between an upper electrode (not shown) provided on the ceiling of the chamber and the base plate 30 of the member for a semiconductor manufacturing equipment 10 to generate plasma. A refrigerant circulates in the refrigerant passage 32 of the base plate 30. Backside gas is introduced into the gas supply path 60a and the gas supply path 60b from a gas cylinder (not shown). The backside gas passes through the gas supply path 60a and the plurality of central portion plugs 55a and is supplied and enclosed in the space between the back surface of the wafer W and the reference surface 21b of the wafer placement surface. Similarly, the backside gas passes through a gas supply path 60b and a plurality of outer peripheral portion plugs 55b, and is supplied and enclosed in the space between the back surface of the focus ring FR and the reference surface 27b of the focus ring placement surface. The presence of this backside gas allows efficient thermal conduction between the wafer W and the ceramic substrate 20, and between the focus ring FR and the ceramic substrate 20.

By embedding the central portion plug 55a and the outer peripheral portion plug 55b in the central portion plug placement hole 50a and the outer peripheral portion plug placement hole 50b, respectively, discharges in the central portion plug placement hole 50a and the outer peripheral portion plug placement hole 50b can be suppressed. If the central portion plug 55a (the outer peripheral portion plug 55b) were not present, electrons generated as a result of ionization of gas molecules by application of an RF voltage would accelerate and collide with other gas molecules, causing a glow discharge and eventually an arc discharge. However, if the central portion plug 55a (the outer peripheral portion plug 55b) is present, the electrons will hit the central portion plug 55a (the outer peripheral portion plug 55b) before colliding with other gas molecules, thereby suppressing discharge.

### 3. Method for Manufacturing a Member for Semiconductor Manufacturing Equipment

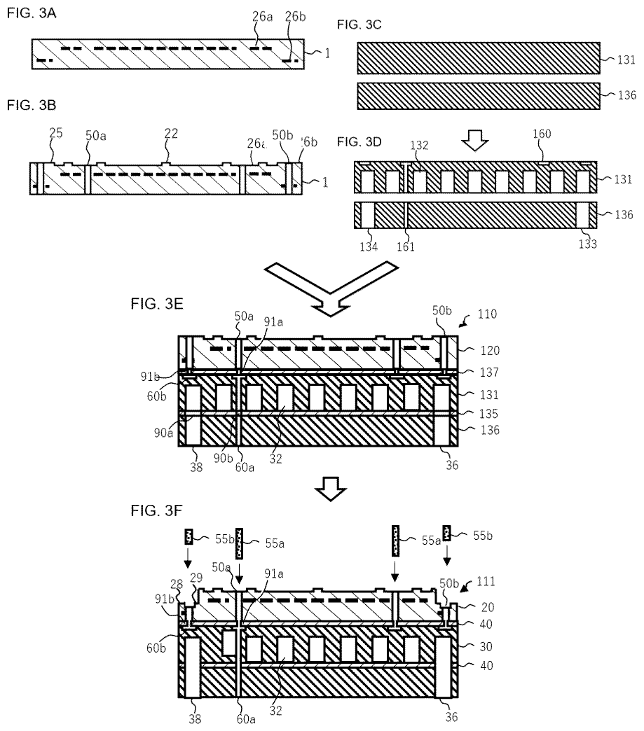

Next, a method for manufacturing the member for a semiconductor manufacturing equipment 10 will be exemplarily described based on FIGS. 3A-3F. First, a disk-shaped ceramic sintered body 120 that is the base of the ceramic substrate 20 is produced by hot-press sintering a ceramic powder formed body (FIG. 3A). The formed body may be manufactured by laminating a plurality of tape formed bodies, by a mold casting method, or by compacting ceramic powder. An electrode 22 is provided inside the ceramic sintered body 120.

Next, the central portion plug placement hole 50a and the outer peripheral portion plug placement hole 50b are formed in the ceramic sintered body 120 by machining. In addition, a plurality of protrusions 22 and a seal band 25 are formed by laser processing on the upper surface of the ceramic sintered body 120 (FIG. 3B). The plurality of protrusions 22 and the seal band 25 may be formed after the ceramic substrate 20 and the base plate 30 are bonded together.

In parallel with this, two MMC disk members 131 and 136 are prepared (FIG. 3C). When the ceramic sintered body 120 is made of alumina, it is preferable that the MMC disk members 131 and 136 be made of SiSiCTi or AlSiC. This is because the coefficient of thermal expansion of alumina is approximately the same as that of SiSiCTi and AlSiC. The MMC disk member made of SiSiCTi can be manufactured, for example, as follows. First, silicon carbide, metal Si, and metal Ti are mixed to produce a powder mixture. Next, the resulting powder mixture is uniaxially pressed to produce a disk-shaped formed body, which is then hot-press sintered in an inert atmosphere to obtain the MMC disk member made of SiSiCTi.

Then, grooves 132, which will eventually become the refrigerant passage 32, are formed on the lower surface of the upper MMC disk member 131 by machining. A through hole 133 for introducing the refrigerant and a through hole 134 for discharging the refrigerant are formed in the lower MMC disk member 136. Further, grooves 160 and through holes 161, which will become the gas supply paths 60a and 60b, are formed on the upper MMC disk member 131 and the lower MMC disk member 136 by machining (FIG. 3D).

Next, metal bonding materials 135 and 137 are prepared. The metal bonding materials 135 and 137 preferably have a thickness of about 100 μm (for example, 80 to 240 μm). The metal bonding material 135 has a through hole 90 a for communicating the refrigerant flow passage of the lower MMC disk member 136 and that of the upper MMC disk member 131. In addition, the metal bonding material 135 also has a through hole 90b for communicating the gas supply passage 60a (gas supply passage 60b) of the lower MMC disk member 136 and that of the upper MMC disk member 131. The metal bonding material 137 has a through hole 91a for communicating the central portion plug placement hole 50a with the gas supply path 60a, and a through hole 91b for communicating the outer peripheral portion plug placement hole 50b with the gas supply path 60b.

The metal bonding material 135 is disposed between the lower surface of the upper MMC disk member 131 and the upper surface of the lower MMC disk member 136, and the metal bonding material 137 is disposed on the upper surface of the upper MMC disk member 131. Next, the ceramic sintered body 120 is placed on the metal bonding material 137 arranged on the top surface of the upper MMC disk member 131. This results in a laminate 110 in which the lower MMC disk member 136, the metal bonding material 135, the upper MMC disk member 131, the metal bonding material 137, and the ceramic sintered body 120 are laminated in this order from the bottom (FIG. 3E).

This laminate 110 is pressed while being heated (TCB) to obtain a bonded body 111 (FIG. 3F). The bonded body 111 is formed by bonding a ceramic sintered body 120 to the upper surface of a base plate 30 via the bonding layer 40. The base plate 30 is formed by bonding an upper MMC disk member 131 and a lower MMC disk member 136 via the bonding layer 40. The base plate 30 has the refrigerant passage 32, a refrigerant introduction portion 36, a refrigerant discharge portion 38, a gas supply path 60a, and a gas supply path 60b.

The TCB is performed, for example, as follows. That is, the

laminate is pressurized and bonded at a temperature no higher than the solidus temperature of the metal bonding material (for example, the temperature 20° C. lower than the solidus temperature or more and no higher than the solidus temperature), and then returned to room temperature. Thereby, the metal bonding material becomes the metal bonding layer. In this case, an Al—Mg based bonding material or an Al—Si—Mg based bonding material can be used as the metal bonding material. For example, when TCB is performed using an Al—Si—Mg based bonding material, the laminate is pressurized in a heated state under a vacuum atmosphere. The metal bonding material preferably has a thickness of approximately 100 μm.

Next, the outer periphery of the ceramic sintered body 120 is cut to form a step, and the seal bands 28, 29 are formed by laser processing (FIG. 3F), thus obtaining the ceramic substrate 20 having a central portion 20a and an outer peripheral portion 20b.

Next, the central portion plugs 55a and the outer peripheral portion plugs 55b are embedded in the central portion plug placement hole 50a and the outer peripheral portion plug placement hole 50b of the ceramic substrate 20, respectively (FIG. 3F). Alternatively, a paste-like ceramic mixture serving as a precursor of the central portion plug 55a and the outer peripheral portion plug 55b may be injected into the central portion plug placement hole 50a and the outer peripheral portion plug placement hole 50b of the ceramic substrate 20 and fired to form the central portion plugs 55a and the outer peripheral portion plugs 55b. Thereafter, the member for a semiconductor manufacturing equipment is completed by appropriately going through processes such as adjusting the overall shape.

In addition, although the base plate 30 in FIG. 1 is described as an integrated component, it may have a structure in which two components are bonded with a metal bonding layer as shown in FIG. 3F, or a structure in which three or more components are bonded with a metal bonding layer. Further, when the bonding layer 40 is formed using the metal bonding material 137, an insulating film may be formed on the side surface of the base plate 30 by thermal spraying either before or after bonding to the ceramic substrate 20. When a resin adhesive sheet is used to form the bonding layer 40, an insulating film may be formed by thermal spraying before bonding to the ceramic substrate 20 in order to prevent the resin from melting.

### DESCRIPTION OF REFERENCE NUMERALS

10: Member for semiconductor manufacturing equipment
20: Ceramic substrate
20a: Central portion
20b: Outer peripheral portion
21: Central portion upper surface
21a: Upper end surface
21b: Reference surface
21c: Upper end surface
22: Protrusion
23: Lower surface
25: Seal band
26a: Electrode
26b: Electrode
27: Outer peripheral portion upper surface
27a: Upper end surface
27b: Reference surface
27c: Upper end surface
28: Seal band
29: Seal band
30: Base plate
31: Upper surface
32: Refrigerant passage
33: Lower surface
36: Refrigerant introduction portion
38: Refrigerant discharge portion
40: Bonding layer
42a: Through hole
42b: Through hole
50a: Central portion plug placement hole
50a1: Upper opening
50a2: Lower opening
50a4: Inner peripheral surface
50b: Outer peripheral portion plug placement hole
50b1: Upper opening
50b2: Lower opening
50b4: Inner peripheral surface
55a: Central portion plug
55a1: Upper surface
55a2: Lower surface
55a3: Gas flow passage
55a4: Outer peripheral surface
55b: Outer peripheral portion plug
55b1: Upper surface
55b2: Lower surface
55b3: Gas flow passage
55b4: Outer peripheral surface
60a: Gas supply path
60b: Gas supply path
61a: Recess
62a: Gas introduction portion
90a: Through hole
90b: Through hole
91a: Through hole
91b: Through hole
110: Laminate
111: Bonded body
120: Ceramic sintered body
131: MMC disc member
132: Groove
133: Through hole
134: Through hole
135: Metal bonding material
136: MMC disc member
137: Metal bonding material
160: Groove
161: Through hole
FR: Focus ring
W: Wafer

1. A member for a semiconductor manufacturing equipment, comprising a ceramic substrate,
wherein the ceramic substrate comprises a central portion with a central portion upper surface on which a wafer is to be placed, and an outer peripheral portion with an outer peripheral portion upper surface on which a focus ring is to be placed, the outer peripheral portion being located on an outer peripheral side of the central portion upper surface and lower than the central portion upper surface,
wherein the central portion comprises a central portion plug placement hole that vertically penetrates the central portion, and a central portion plug that is embedded in the central portion plug placement hole, and
wherein the outer peripheral portion comprises an outer peripheral portion plug placement hole that vertically penetrates the outer peripheral portion, and an outer peripheral portion plug embedded in the outer peripheral portion plug placement hole and having a lower relative permittivity than the central portion plug.

2. The member for a semiconductor manufacturing equipment according to claim 1, wherein the relative permittivity of the outer peripheral portion plug is 0.7 times or less than the relative permittivity of the central portion plug.

3. The member for a semiconductor manufacturing equipment according to claim 1, wherein a main component of the central portion plug is the same as a main component of the ceramic substrate.

4. The member for a semiconductor manufacturing equipment according to claim 1, wherein the outer peripheral portion plug comprises silica.

5. The member for a semiconductor manufacturing equipment according to claim 1, wherein the central portion plug and/or the outer peripheral portion plug is a porous body, or a dense body with a flow passage passing an inside the dense body.

6. The member for a semiconductor manufacturing equipment according to claim 1, wherein a thickness of the outer peripheral portion is 75% or less of the thickness of the central portion.
